(19) United States
(12) Patent Application Publication
(10) Pub. No.: US 2015/0021591 A1
(43) Pub. Date: Jan. 22, 2015

(54) THIN FILM TRANSISTOR AND THIN FILM TRANSISTOR ARRAY PANEL INCLUDING THE SAME

(71) Applicant: Samsung Display Co., Ltd., Yongin-City (KR)

(72) Inventors: Jung-Bae Kim, Yongin-City (KR); Bo-Yong Chung, Yongin-City (KR); Hae-Yeon Lee, Yongin-City (KR); Hai-Jung In, Yongin-City (KR)

(73) Assignee: Samsung Display Co., Ltd., Yongin-City (KR)

(21) Appl. No.: 14/133,307

(22) Filed: Dec. 18, 2013

(30) Foreign Application Priority Data
Jul. 22, 2013 (KR) 10-2013-0086231

(51) Int. Cl. H01L 29/786

(52) U.S. Cl. CPC H01L 29/7869; H01L 29/78645
USPC 257/43; 257/66

(57) ABSTRACT

A thin film transistor is disclosed. In one aspect, the thin film transistor includes a substrate, a semiconductor layer formed on the substrate, and a first gate electrode substantially overlapping the semiconductor layer with a gate insulating layer interposed therebetween. The thin film transistor also includes a second gate electrode substantially overlapping the first gate electrode with an interlayer insulating layer interposed therebetween, and a source electrode and a drain electrode electrically connected to the semiconductor layer, wherein the first gate electrode is electrically connected to the second gate electrode.

### CROSS-REFERENCE TO RELATED APPLICATIONS

Any and all applications for which a foreign or domestic priority claim is identified in the Application Data Sheet as filed with the present application are hereby incorporated by reference under 37 CFR 1.57.

This application claims priority to and the benefit of Korean Patent Application No. 10-2013-0086231 filed in the Korean Intellectual Property Office on Jul. 22, 2013, the entire contents of which are incorporated herein by reference.

### BACKGROUND

1. Field

The described technology generally relates to a thin film transistor and a thin film transistor array panel including the same.

2. Description of the Related Technology

Thin film transistors (TFTs) are used in various electronic devices such as a flat panel displays and the like. For example, thin film transistors can be used as a switching element or a driving element in a liquid crystal display (LCD), an organic light-emitting diode (OLED) display, an electrophoretic display, or the like.

When employed in a flat panel display, a thin film transistor typically includes a gate electrode receiving a gate signal from a gate line, a source electrode receiving a data signal to be applied to a pixel electrode from a data line, a drain electrode facing the source electrode, and a semiconductor layer electrically connected to the source electrode and the drain electrode.

Furthermore, in the standard flat panel display, the data signal is transmitted to the pixel electrode or the driving transistor in response to sequentially transmitted gate signals.

The above information disclosed in this Background section is only intended to facilitate understanding of the background of the described technology and therefore it may contain information that does not constitute the prior art that is already known in this country to a person of ordinary skill in the art.

### SUMMARY OF CERTAIN INVENTIVE ASPECTS

One inventive aspect is a thin film transistor with a substantially minimized signal delay caused by parasitic capacitance between a gate electrode and source and drain electrodes and wiring resistance, and a thin film transistor array panel including the same.

Another aspect is a thin film transistor including a substrate, a semiconductor layer formed on the substrate, a first gate electrode substantially overlapping the semiconductor layer with a gate insulating layer interposed therebetween, a second gate electrode substantially overlapping the first gate electrode with an interlayer insulating layer interposed therebetween, and source and drain electrodes connected to the semiconductor layer, wherein the first gate electrode and the second gate electrode are electrically connected.

The first gate electrode may be positioned between the substrate and the semiconductor layer.

The thickness of the first gate electrode may be greater than the thickness of the second gate electrode.

The thickness of the interlayer insulating layer may be substantially equal to or greater than the thickness of the gate insulating layer.

A protective layer may be positioned between the source and drain electrodes and the semiconductor layer, and the source and drain electrodes may be respectively connected to a source region and a drain region of the semiconductor layer through a contact hole formed in the protective layer.

A connection bridge may be formed on the protective layer, and the connection bridge may electrically connect the first gate electrode and the second gate electrode through a contact hole.

The connection bridge may be formed of substantially the same material as the source electrode and the drain electrode.

A protective layer may be formed in contact with a channel region of the semiconductor layer and may substantially overlap the channel region.

The protective layer may have a substantially planar shape and the first gate electrode may have substantially the same shape as the protective layer.

The semiconductor layer may be positioned between the first gate electrode and the substrate.

The thickness of the first gate electrode may be greater than the thickness of the second gate electrode and the thickness of the interlayer insulating layer may be substantially equal to or greater than the thickness of the gate insulating layer.

The source electrode may include first and second source electrodes, the drain electrode may include first and second drain electrodes, the first source electrode and the first drain electrode may be formed separated on the substrate and substantially overlapping the semiconductor layer, and a second source electrode and a second drain electrode may be respectively connected to the first source electrode and the first drain electrode through a contact hole.

The second gate electrode may be formed of substantially the same material as the second source electrode and the second drain electrode.

A protective layer may be formed on the second gate electrode and the second source electrode and the second drain electrode may be formed on the protective layer.

The second gate electrode may be electrically connected to the first gate electrode through a contact hole formed in the interlayer insulating layer.

The second gate electrode may be positioned within a boundary of the first gate electrode.

Portions of the source electrode and the drain electrode may substantially overlap the first gate electrode and a region of the semiconductor layer may be interposed between the overlap between the source and drain electrodes and the first gate electrode.

The semiconductor layer may be formed of an oxide semiconductor.

Another aspect is a thin film transistor array panel including a substrate, a gate line formed on the substrate, a thin film transistor connected to the gate line, a data line electrically connected to the thin film transistor, and a pixel electrode connected to the thin film transistor, wherein the thin film transistor includes a first gate electrode substantially overlapping a semiconductor layer with a gate insulating layer interposed therebetween, and a second gate electrode substantially overlapping the first gate electrode with an interlayer insulating layer interposed therebetween and wherein the first gate electrode is electrically connected to the second gate electrode.

The first gate electrode may be positioned within a boundary of the second gate electrode.

A source electrode and a drain electrode may substantially overlap the first gate electrode, and a region of the semiconductor layer may be interposed between the overlap between the source and drain electrodes and the first gate electrode.

The semiconductor layer of the thin film transistor may be formed of an oxide semiconductor.

The thickness of the interlayer insulating layer may be substantially equal to or greater than the thickness of the gate insulating layer, and the thickness of the first gate electrode may be greater than the thickness of the second gate electrode.

The second gate electrode may be connected to the first gate electrode through a contact hole.

A connection bridge may be formed separated from the source electrode and the drain electrode and electrically connecting the first gate electrode to the second gate electrode.

The source electrode may include first and second source electrodes electrically connected to each other, the drain electrode may include first and second drain electrodes electrically connected to each other, and the first source electrode and the first drain electrode may be formed on the substrate and separated from each other.

The data line may be connected to the second drain electrode, and the thickness of the first drain electrode may be less than the thickness of the first drain electrode.

According to at least one embodiment, since the gate electrodes substantially overlap each other with the insulating layer interposed therebetween, the thin film transistor can reduce the signal delay due to wire resistance and parasitic capacitance.

### BRIEF DESCRIPTION OF THE DRAWINGS

FIG. 1 is a top plan view of a thin film transistor according to an exemplary embodiment.

FIG. 2 is a cross-sectional view taken along line II-II of FIG. 1.

FIG. 3 is a cross-sectional view taken along line III-III of FIG. 1.

FIG. 4 is a cross-sectional view of a thin film transistor according to another exemplary embodiment taken along line III-III of FIG. 1.

FIG. 5 is a top plan view of a thin film transistor according to another exemplary embodiment.

FIG. 6 is a cross-sectional view taken along line VI-VI of FIG. 5.

FIG. 7 is a top plan view of a thin film transistor according to yet another exemplary embodiment.

FIG. 8 is a cross-sectional view taken along line VIII-VIII of FIG. 7.

FIG. 9 and FIG. 10 are cross-sectional views of thin film transistors according to exemplary embodiments.

FIG. 11 is a layout view of a thin film transistor array panel according to another exemplary embodiment.

FIG. 12 is an equivalent circuit of one pixel of an organic light-emitting diode (OLED) display according to another exemplary embodiment.

### DETAILED DESCRIPTION OF CERTAIN INVENTIVE EMBODIMENTS

As the resistance of the wires in a flat panel display increases, signal delays can be generated and the time period required to sequentially turn on and off the driving transistors in response to the gate signals increases. The result may be that it is not possible to sequentially drive all of the thin film transistors within the required time period.

Additionally, there is parasitic capacitance between the gate electrode and the source/drain electrodes which can cause an additional signal delay.

The described technology will be described more fully hereinafter with reference to the accompanying drawings, in which exemplary embodiments of the described technology are shown.

The drawings and description are to be regarded as illustrative in nature and not restrictive. Like reference numerals designate like elements throughout the specification.

Furthermore, the size and thickness of the respective structural components shown in the drawings may be exaggerated for clarity, however, the described technology is not limited thereto.

In the drawings, the thickness of layers, films, panels, areas, regions, etc., may be exaggerated for clarity. It will be understood that when an element such as a layer, film, region, or array panel is referred to as being “on” another element, it can be directly on the other element or intervening elements may also be present. Additionally, the term “connected” as used herein also includes the term “electrically connected.”

Next, a thin film transistor and a thin film transistor array panel according to the described technology will be described with reference to accompanying drawings.

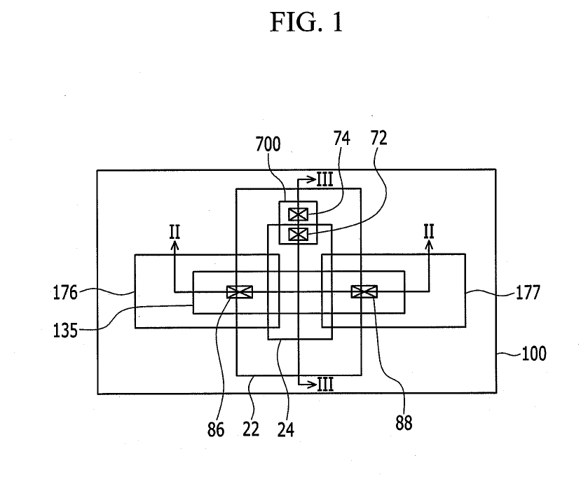

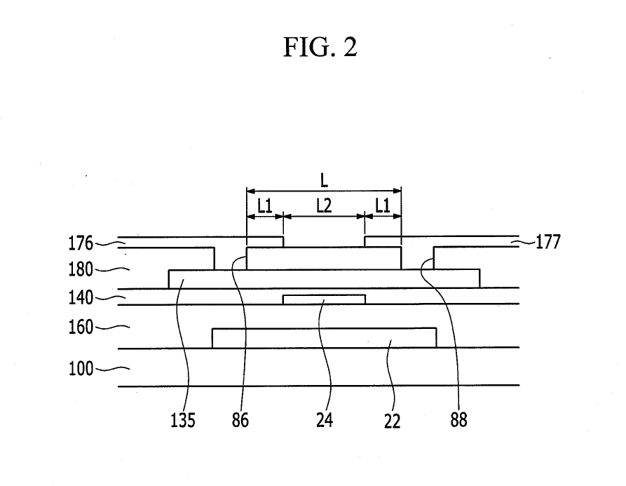

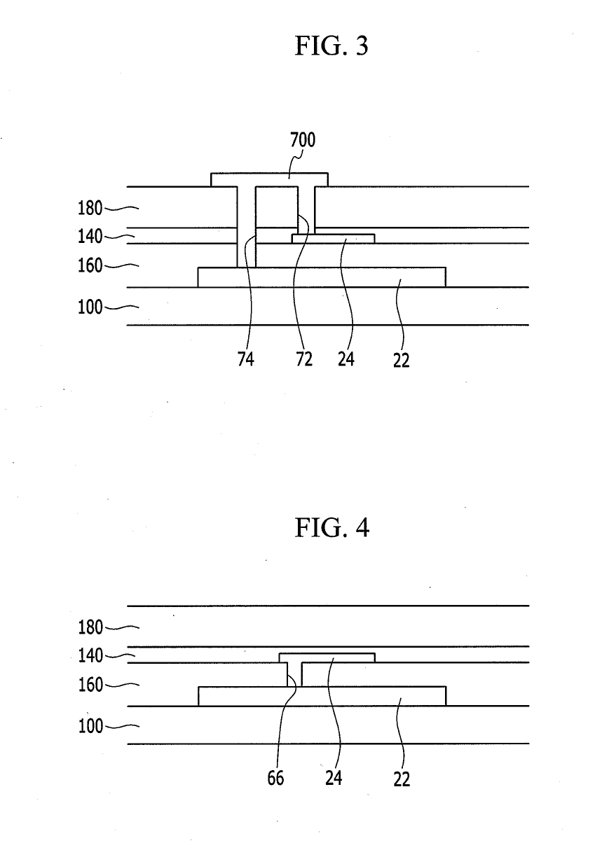

FIG. 1 is a top plan view of a thin film transistor according to an exemplary embodiment and FIG. 2 is a cross-sectional view taken along line II-II of FIG. 1. FIG. 3 is a cross-sectional view taken along line III-III of FIG. 1 and FIG. 4 is a cross-sectional view of a thin film transistor according to another exemplary embodiment taken along line III-III of FIG. 1.

As shown in FIG. 1 to FIG. 3, the thin film transistor includes a first gate electrode 22 formed on a substrate 100.

According to some embodiments, the substrate 100 is a transparent electrically insulating substrate formed of glass, quartz, ceramic, plastic, or the like, or the substrate 100 may be a metallic substrate formed of stainless steel or the like.

The first gate electrode 22 may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), or titanium (Ti). Alternatively, the first gate electrode 22 may have a multilayered structure including at least two conductive layers having different physical properties.

An interlayer insulating layer 160 is formed on the first gate electrode 22.

The interlayer insulating layer 160 may include an electrically insulating material such as tetraethyl orthosilicate (TEOS), silicon oxide (SiOx), silicon nitride (SiNx), or silicon oxynitride (SiON).

A second gate electrode 24 is formed on the interlayer insulating layer 160. The thickness of the second gate electrode 24 may be less than that of the first gate electrode 22. The thickness of the first gate electrode 22 may be about two or three times that of the second gate electrode 24. As shown in FIG. 1, the second gate electrode 24 may be positioned within the boundary of the first gate electrode 22.

The second gate electrode 24 may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), or titanium (Ti). Alternatively, the second gate electrode 24 may have a multilayered structure including at least two conductive layers having different physical properties.

A gate insulating layer 140 is formed on the second gate electrode 24. The gate insulating layer 140 may have a thickness that is substantially equal to or less than that of the interlayer insulating layer 160.

The gate insulating layer 140 include an electrically insulating material such as tetraethyl orthosilicate (TEOS), silicon oxide (SiOx), silicon nitride (SiNx), or silicon oxynitride (SiON).

A semiconductor layer 135 is formed on the gate insulating layer 140, and the semiconductor layer 135 substantially overlaps the first gate electrode 22 and the second gate electrode 24.

The semiconductor layer 135 may be divided into a channel region, and a source region and a drain region formed at respective sides of the channel region. The channel is formed between the source electrode and the drain electrode.

The semiconductor layer 135 may be formed of a polysilicon (poly-Si) or oxide semiconductor 135. The oxide semiconductor 135 may include any one of an oxide having a base including titanium (Ti), hafnium (Hf), zirconium (Zr), aluminum (Al), tantalum (Ta), germanium (Ge), zinc (Zn), gallium (Ga), tin (Sn), or indium (In), and complex oxides thereof. For example, the complex oxides may include zinc oxide (ZnO), indium-gallium-zinc oxide (InGaZnO4), indium-zinc oxide (Zn—In—O), zinc-tin oxide (Zn—Sn—O), indium-gallium oxide (In—Ga—O), indium-tin oxide (In—Sn—O), indium-zirconium oxide (In—Zr—O), indium-zirconium-zinc oxide (In—Zr-Zn-O), indium-zirconium-tin oxide (In—Zr—Sn—O), indium-zirconium-gallium oxide (In—Zr—Ga—O), indium-aluminum oxide (In—Al—O), indium-zinc-aluminum oxide (In—Zn—Al—O), indium-tin-aluminum oxide (In—Sn—Al—O), indium-aluminum-gallium oxide (In—Al—Ga—O), indium-tantalum oxide (In—Ta—O), indium-tantalum-zinc oxide (In—Ta—Zn—O), indium-tantalum-tin oxide (In—Ta—Sn—O), indium-tantalum-gallium oxide (In—Ta—Ga—O), indium-germanium oxide (In—Ge—O), indium-germanium-zinc oxide (In—Ge—Zn—O), indium-germanium-tin oxide (In—Ge—Sn—O), indium-germanium-gallium oxide (In—Ge-Ga-O), titanium-indium-zinc oxide (Ti—In—Zn—O), and hafnium-indium-zinc oxide (Hf—In—Zn—O).

A protective layer 180 is formed on the semiconductor layer 135.

The protective layer 180 includes contact holes 86 and 88 exposing the source region and the drain region of the semiconductor layer 135. The protective layer 180 and the gate insulating layer 140 include a contact hole 72 exposing the second gate electrode 24 and the protective layer 180, the gate insulating layer 140, and the interlayer insulating layer 160 include a contact hole 74 exposing the first gate electrode 22.

The protective layer 180 includes an electrically insulating material such as tetraethyl orthosilicate (TEOS), silicon oxide (SiOx), silicon nitride (SiNx), or silicon oxynitride (SiON).

A connection bridge 700, a source electrode 176, and a drain electrode 177 are formed on the protective layer 180.

In some embodiments, portions of the source electrode 176 and the drain electrode 177 substantially overlap the first gate electrode 22. A region of the semiconductor layer 135 is interposed between the overlap between the source and drain electrodes 176 and 177 and the first gate electrode 22.

The source and drain electrodes 176 and 177 may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), or titanium (Ti). Alternatively, the source and drain electrodes 176 and 177 may have a multilayered structure including at least two conductive layers having different physical properties. For example, the source and drain electrodes 176 and 177 can include a triple layer such as Ti/Cu/Ti, Ti/Ag/Ti, or Mo/Al/Mo.

The connection bridge 700 may be formed of substantially the same material as the source and drain electrodes 176 and 177, and is electrically connected to the first gate electrode 22 and the second gate electrode 24 through the contact holes 72 and 74.

According to another embodiment, the first and second gate electrodes 22 and 24 is directly connected through a contact hole 66 formed in the interlayer insulating layer 160, as shown in FIG. 4.

According to at least one embodiment, when the first and second gate electrodes 22 and 24 are formed with the above described structure, the channel of the semiconductor layer 135 of the thin film transistor can have an increased current. Additionally, the parasitic capacitance between the source and drain electrodes 176 and 177, and the gate electrode, can be decreased. These advantages will be described in greater detail below.

Referring to FIG. 2, by forming the first and second gate electrode 22 and 24 to be electrically connected, the first gate electrode 22 may be formed with an increased thickness.

That is, when the first gate electrode 22 is formed with an increased thickness, the resistance of the wire including the first gate electrode 22 is decreased resulting in a reduced signal delay due to the wire resistance.

The interlayer insulating layer 160 has a substantially step shape since it is formed on the first gate electrode 22. In some embodiments, the interlayer insulating layer 160 has a thickness to sufficiently cover the first gate electrode 22.

Additionally, the second gate electrode 24 is connected to the first gate electrode 22 to receive the signal from the first gate electrode 24. As discussed above, due to the configuration of the first gate electrode 24, the signal delay due to the wire resistance is reduced. Accordingly, the second gate electrode 24 may be formed with a thickness less that of the first gate electrode 22.

Consequently, since the second gate electrode 24 is relatively thin, the thickness of the gate insulating layer 140 formed on the second gate electrode 24 may be reduced. Since the thickness of the gate insulating layer 140 is reduced, the distance between the semiconductor layer 135 and the second gate electrode 23 is decreased, resulting in a stronger electric field formed therebetween and increasing the on-current of the transistor.

The first gate electrode 22, and the source electrode and drain electrodes 176 and 177, may substantially overlap each other such that an electric field can be formed therebetween for initial charge injection into the semiconductor layer 135.

If the first gate electrode 22 substantially overlaps the source and drain electrodes 176 and 177, a parasitic capacitance is generated therebetween. However, according to at least one embodiment, when forming the first and second gate electrodes 22 and 24, both the interlayer insulating layer 160 and the gate insulating layer 140 are positioned between the first gate electrode 22 and the source and drain electrodes 176 and 177, such that the distance therebetween is increased.

Accordingly, the parasitic capacitance between the source and drain electrodes 176 and 177 and the gate electrode may be reduced, thereby reducing the signal delay.

As described above, due to the structure of the first and second gate electrodes 22 and 24, the channel region includes a first channel region L1 formed in the portions of the semiconductor layer 135 substantially overlapping the source and drain electrodes 176 and 177 next to the connection to the source and drain electrodes 176 and 177 within the contact holes 86 and 88. The channel region also includes a second channel region L2 formed in the semiconductor layer 135 between the ends of the source and drain electrodes 176 and 177.

The second gate electrode 24 and the semiconductor layer 135 are separated by the gate insulating layer 140 which is relatively thin such that a strong electric field is formed in the second channel region L2, thereby increasing the current through the second channel region L2.

The first channel region L1 forms a weak electric field through the insulation layers such as the protective layer 180, the gate insulating layer 140, and the interlayer insulating layer 160 between the first gate electrode 22 and the source and drain electrodes 176 and 177. However, the weak electric field is sufficient to inject an initial charge into the first channel region L1 to allow current to flow through the channel region of the semiconductor layer 135.

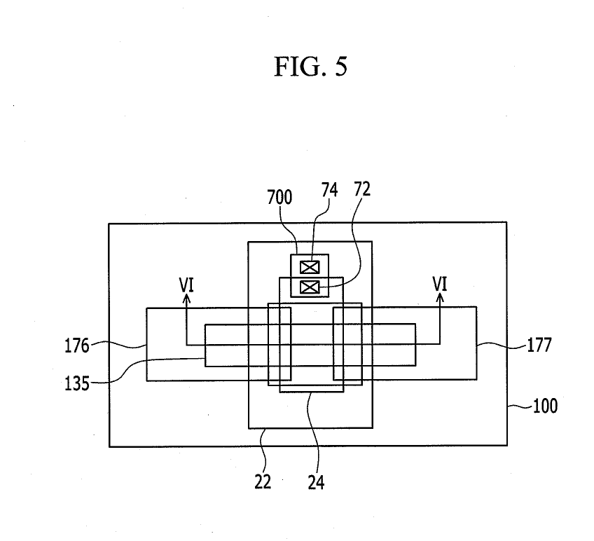

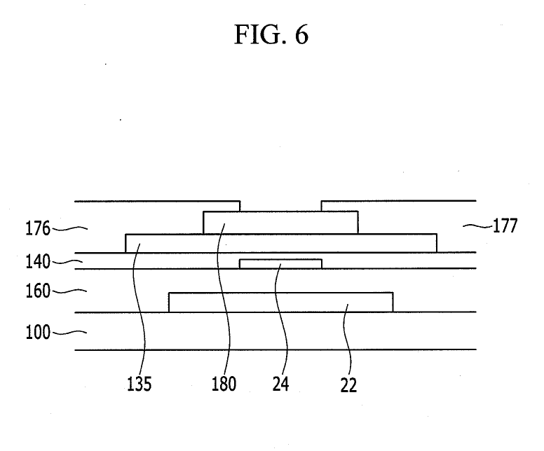

FIG. 5 is a top plan view of a thin film transistor according to another exemplary embodiment, and FIG. 6 is a cross-sectional view taken along line VI-VI of FIG. 5.

Since most of the interlayer configuration is the same as that of the embodiment illustrated in FIG. 1 and FIG. 2, only elements which differ from the previous embodiments will be described in detail.

The thin film transistor of FIG. 5 and FIG. 6 includes the substrate 100, the first gate electrode 22 formed on the substrate 100, the interlayer insulating layer 160 formed on the first gate electrode 22, and the second gate electrode 24 formed on the interlayer insulating layer 160. The thin film transistor also includes the gate insulating layer 140 formed on the second gate electrode 24, the semiconductor layer 135 formed on the gate insulating layer 140, and the protective layer 180 formed on the semiconductor layer 135. The connection bridge 700, the source electrode 176, and the drain electrode 177 are formed on the protective layer 180. The connection bridge 700 electrically connects the first gate electrode 22 to the second gate electrode 24 through the contact holes 72 and 74.

The protective layer 180 is only positioned on the channel region of the semiconductor layer 135 to protect the channel region, and exposes the source region and the drain region of the semiconductor layer 135.

Accordingly, the source and drain electrodes 176 and 177 are respectively connected to the exposed source and drain regions without contact holes. The source and drain electrodes 176 and 177 may be deposited over the semiconductor layer 135 and the protective layer 180 to form a substantially step shaped structure. Thus, since the contact holes are omitted, the size of the first gate electrode 22 may be decreased.

For example, if contact holes 86 and 88 are employed as in the embodiment illustrated in FIGS. 1 to 3, the area of the semiconductor layer 135 is increased by the area occupied by the contact holes 86 and 88, and therefore, the area of the first gate electrode 22 is also increased. However, in the case that the contact holes are omitted, only the area where the semiconductor layer 135 contacts the source and drain electrodes 176 and 177 is exposed, reducing the area of the semiconductor layer 135 when compared with the case of forming the contact holes. Accordingly, the area of the first gate electrode 22 may also be reduced.

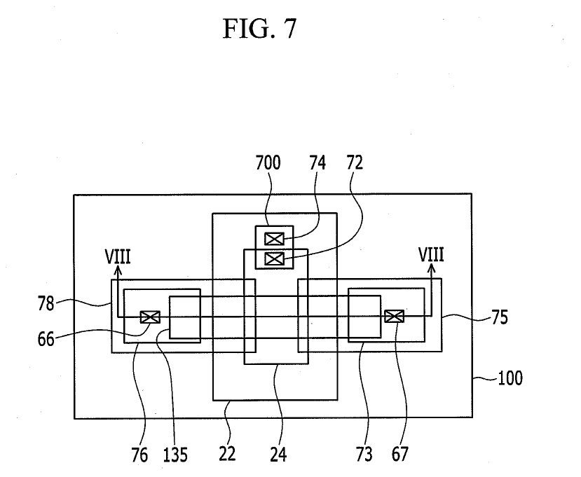

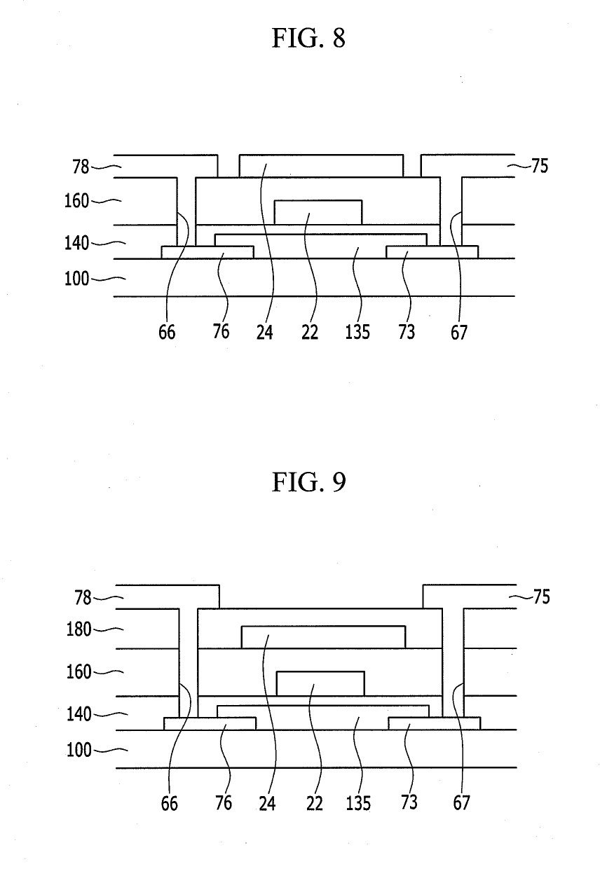

FIG. 7 is a top plan view of a thin film transistor according to another exemplary embodiment, and FIG. 8 is a cross-sectional view taken along line VIII-VIII of FIG. 7.

As shown in FIG. 7 and FIG. 8, in the thin film transistor according to the present embodiment, a first source electrode 76 and a first drain electrode 73 are formed on the substrate 100.

The substrate 100 may be a transparent electrically insulating substrate made of glass, quartz, ceramic, or plastic, or a metal substrate made of stainless steel.

The first source electrode 76 and the first drain electrode 73 are separated from each other and may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), or titanium (Ti). Alternatively, the first source and first drain electrodes 76 and 73 may have a multilayered structure including at least two conductive layers having different physical properties.

The semiconductor layer 135 is formed on the first source electrode 76 and the first drain electrode 73 and is electrically connected to the first source electrode 76 and the first drain electrode 73.

The semiconductor layer 135 may be divided into the channel region, and the source region and drain region formed at respective sides of the channel region. The channel region is formed between the first source electrode 76 and the first drain electrode 73.

The semiconductor layer 135 may be formed of a polysilicon (poly-Si) or oxide. The oxide semiconductor 135 may include any one of an oxide having a base including titanium (Ti), hafnium (Hf), zirconium (Zr), aluminum (Al), tantalum (Ta), germanium (Ge), zinc (Zn), gallium (Ga), tin (Sn), or indium (In), and complex oxides thereof. For example, the complex oxides may include zinc oxide (ZnO), indium-gallium-zinc oxide (InGaZnO4), indium-zinc oxide (Zn—In—O), zinc-tin oxide (Zn—Sn—O), indium-gallium oxide (In—Ga—O), indium-tin oxide (In—Sn—O), indium-zirconium oxide (In—Zr—O), indium-zirconium-zinc oxide (In—Zr-Zn-O), indium-zirconium-tin oxide (In—Zr—Sn—O), indium-zirconium-gallium oxide (In—Zr—Ga—O), indium-aluminum oxide (In—Al—O), indium-zinc-aluminum oxide (In—Zn—Al—O), indium-tin-aluminum oxide (In—Sn—Al—O), indium-aluminum-gallium oxide (In—Al—Ga—O), indium-tantalum oxide (In—Ta—O), indium-tantalum-zinc oxide (In—Ta—Zn—O), indium-tantalum-tin oxide (In—Ta—Sn—O), indium-tantalum-gallium oxide (In—Ta—Ga—O), indium-germanium oxide (In—Ge—O), indium-germanium-zinc oxide (In—Ge—Zn—O), indium-germanium-tin oxide (In—Ge—Sn—O), indium-germanium-gallium oxide (In—Ge-Ga-O), titanium-indium-zinc oxide (Ti—In—Zn—O), and hafnium-indium-zinc oxide (Hf—In—Zn—O).

The gate insulating layer 140 is formed on the semiconductor layer 135.

The gate insulating layer 140 may include an electrically insulating material such as tetraethyl orthosilicate (TEOS), silicon oxide (SiOx), silicon nitride (SiNx), or silicon oxynitride (SiON).

The first gate electrode 22 is formed on the gate insulating layer 140.

The first gate electrode 22 may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), or titanium (Ti). Alternatively, the gate electrode 22 may have a multilayered structure including at least two conductive layers having different physical properties.

The interlayer insulating layer 160 is formed on the first gate electrode 22.

The interlayer insulating layer 160 may include an electrically insulating material such as tetraethyl orthosilicate (TEOS), silicon oxide (SiOx), silicon nitride (SiNx), or silicon oxynitride (SiON).

The second gate electrode 24 is formed on the interlayer insulating layer 160.

The second gate electrode 24 may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), or titanium (Ti). Alternatively, the gate electrode 124 may have a multilayered structure including at least two conductive layers having different physical properties.

Portions of the first source electrode 76 and the first drain electrode 73 substantially overlap the second gate electrode 24. A region of the semiconductor 135 is interposed between the overlap between the first source and first drain electrodes 76 and 73 and the second gate electrode 24.

The thickness of the interlayer insulating layer 160 may be greater than or substantially equal to the thickness of the gate insulating layer 140.

The interlayer insulating layer may include an electrically insulating material such as tetraethyl orthosilicate (TEOS), silicon oxide (SiOx), silicon nitride (SiNx), or silicon oxynitride (SiON).

The connection bridge 700, a second source electrode 78, and a second drain electrode 75 are formed on the interlayer insulating layer 160. The second source electrode 78 and the second drain electrode 75 may be formed with a thickness greater than that of the first source electrode 76 and the first drain electrode 73.

The second source and second drain electrodes 78 and 75 may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), or titanium (Ti). Alternatively, the second source and second drain electrodes 78 and 75 may have a multilayered structure including at least two conductive layers having different physical properties, for example, a triple layer such as Ti/Cu/Ti, Ti/Ag/Ti, and Mo/Al/Mo.

The connection bridge 700 may be formed of substantially the same material as the second source and second drain electrodes 78 and 75, and electrically connects the first gate electrode 22 to the second gate electrode 24 through the contact holes 72 and 74. Also, as shown in FIG. 8, the first source and first drain electrodes 76 and 73 may be directly connected to the second source and second drain electrodes 78 and 75 through contact holes 66 and 67 formed through the interlayer insulating layer 160 and the gate insulating layer 140.

In this way, the source electrode is formed of the first source electrode 76 and the second source electrode 78 and the drain electrode is formed of the first drain electrode 73 and the second drain electrode 75. Consequently, the thickness of the gate insulating layer 140 may be reduced such that the on current of the transistor may be increased.

That is, the first source electrode 76 transmits the signal received from the second source electrode 78 to the source region and the signal delay due to the wire resistance is small. Accordingly, the thickness of first source electrode 76 may be less than that of the second source electrode 78.

Also, the semiconductor 135 and the first source electrode 76 are connected, thereby forming the semiconductor 135 with a substantially step shape. Due to the substantially step shape of the semiconductor 135, the thickness of the semiconductor 135 is increased, and thereby the thickness of the gate insulating layer 140 may be formed to be relatively thin.

Accordingly, the distance between the gate insulating layer 140 and the first gate electrode 22 can be reduced such that the on current of the transistor is increased.

Additionally, the thickness of the first gate electrode 22 may be sufficiently formed to be relatively thick so that the signal delay due to the wire resistance may be reduced. Also, as the thickness of the first gate electrode 22 is increased, the thickness of the interlayer insulating layer 160 is increased such that the parasitic capacitance formed between the first source and first drain electrodes 76 and 73, and the second gate electrode 24, is decreased.

Further, the thickness of the second gate electrode 24 may be greater than that of the second gate electrode 24 of the embodiment illustrated in FIG. 1 and FIG. 2 in consideration of the signal delay due to the wire resistance.

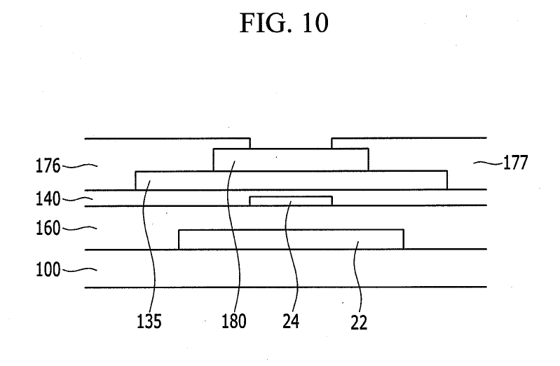

FIG. 9 and FIG. 10 are cross-sectional views of a thin film transistor according to another exemplary embodiment.

FIG. 9 is a cross-sectional view taken along the line VIII-VIII of FIG. 7, and FIG. 10 is a cross-sectional view taken along the line VI-VI of FIG. 5.

Since most of the interlayer configuration is the same as that of FIG. 1 to FIG. 8, only elements which differ from the previous embodiments will be described in detail.

In the thin film transistor of FIG. 9, the protective layer 180 is formed between the second gate electrode 24 and the second source and second drain electrodes 78 and 75.

According to embodiments, the first gate electrode 22 and the second gate electrode 24 are connected to a first wire and receive a gate signal from the first wire. The second source electrode 78 is connected to a second wire and receives a data signal from the second wire. The protective layer 180 is interposed between the first and second wires to substantially prevent a short circuit therebetween.

In the thin film transistor of FIG. 10, and as in FIG. 5 and FIG. 6, the protective layer 180 is only formed on the channel region and has substantially the same planar shape as the first gate electrode 22. The protective layer 180 may be a photosensitive organic material.

Since the protective layer 180 is formed of a photosensitive organic material, a rear exposure may be applied by using the first gate electrode 22 as an exposure mask. Accordingly, the protective layer 180 of FIG. 10 is formed with substantially the same planar shape as the first gate electrode 22.

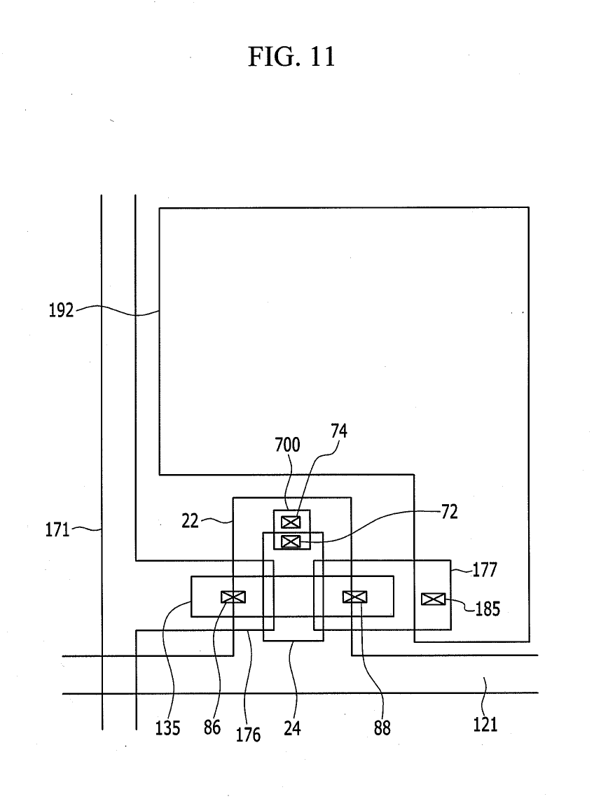

The thin film transistor according to at least one embodiment may be used in a thin film transistor array panel for a display device. This will be described in detail with reference to FIG. 11.

FIG. 11 is a layout view of a thin film transistor array panel according to an exemplary embodiment.

The thin film transistor array panel of FIG. 11 including the thin film transistor of FIG. 1 to FIG. 3 will be described as an example. Accordingly, most of the interlayer configuration is similar to that of FIG. 1 to FIG. 3 and only elements and configurations which differ from the previously embodiments will be described in detail.

As shown in FIG. 11, a plurality of gate lines 121 are formed on a substrate (not shown).

The gate lines 121 transmit gate signals and extend in a transverse direction. Each gate line 121 includes a plurality of first gate electrodes 22 protruding from the gate line 121.

The first gate electrode 22 is electrically connected to the second gate electrode 24 with the interlayer insulating layer 160 interposed therebetween. The first gate electrode 22 and the second gate electrode 24 are electrically connected through the connection bridge 700 formed through the contact holes 72 and 74.

The gate insulating layer 140 is formed on the second gate electrode 24 and the semiconductor 135 is formed on the gate insulating layer 140.

The protective layer 180 is formed on the semiconductor 135 and has contact holes 86 and 88 exposing the source and drain regions of the semiconductor 135.

A plurality of data lines 171 and drain electrodes 177 are formed on the protective layer.

The data line 171 transmits data signals and extends in a longitudinal direction thereby intersecting the gate line 121.

The data line 171 includes the source electrode 176 connected to the source region of the semiconductor 135 through the contact hole 86.

An insulating layer is formed on the data line 171 and the drain electrode 177, and a pixel electrode 192 is formed on the insulating layer. The insulating layer is formed of an inorganic electrically insulating material such as silicon nitride or silicon oxide, an organic electrically insulating material, or a low dielectric constant electrically insulating material. The organic electrically insulating material and the low dielectric constant electrically insulating material are formed to be relatively thick, thereby substantially flattening the top of the substrate.

The pixel electrode 192 is electrically connected to the drain electrode 177 through a contact hole 185 thereby receiving the data signal.

The pixel electrode 192 is made of a material such as a transparent conducting material. For example, the transparent conducting material may be indium tin oxide (ITO), indium zinc oxide (IZO), or ZnO (zinc oxide).

The above thin film transistor array panel may be used as a substrate of a lower array panel of a liquid crystal display (LCD) or an organic light-emitting diode (OLED) display.

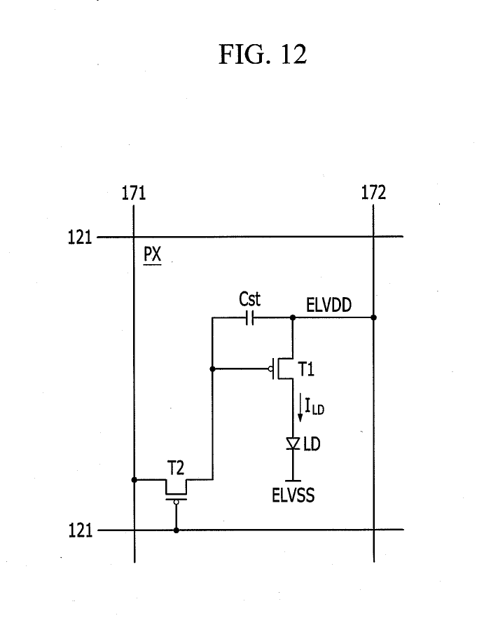

FIG. 12 is an equivalent circuit of one pixel of an OLED display according to another exemplary embodiment.

As shown in FIG. 12, one pixel PE has a 2Tr-1 Cap structure having an OLED LD, two thin film transistors (TFT) T1 and T2, and one capacitor Cst. However, the described technology is not limited thereto. In some embodiments, the OLED display may include three or more thin film transistors and two or more capacitors in one pixel PE and may include a variety of different structures including additional wiring. A compensation circuit can be formed using the additional thin film transistors and capacitors.

The compensation circuit suppresses the occurrence of image quality defects by improving the uniformity of the OLED LD formed in each pixel PE. In general, the compensation circuit includes 2 to 8 thin film transistors.

The OLED LD includes an anode electrode, a cathode electrode, and an organic emission layer disposed between the anode and cathode electrodes. The anode and cathode electrodes are respectively a hole injection electrode and an electron injection electrode.

In an exemplary embodiment, one pixel PE includes the first thin film transistor T1 and the second thin film transistor T2.

The first thin film transistor T1 and the second thin film transistor T2 respectively include a gate electrode, a semiconductor, a source electrode, and a drain electrode. The semiconductor of at least one of the first and second thin film transistors T1 and T2 is formed of an oxide semiconductor. The source and drain electrodes of at least one of the first and second thin film transistors T1 and T2 may include at least one of ITO and IZO of the transparent conductive material, and may be formed of substantially the same material as the anode of the OLED.

The data line 171 is connected to the source electrode of the second thin film transistor T2, and the gate line 121 is connected to the gate electrode of the second thin film transistor T2. The drain electrode of the second thin film transistor T2 is connected to the capacitor Cst. The gate electrode of the first thin film transistor T1 is connect to a node formed between the drain electrode of the second thin film transistor T2 and the capacitor Cst. Also, the source electrode of the first thin film transistor T1 is connected to a common power line 172, and the drain electrode is connected to the anode of the OLED LD.

The second thin film transistor T2 is used as a switch for selecting the pixels to emit light. The second thin film transistor T2 is substantially instantly turned on and the capacitor Cst is charged. The voltage that the capacitor Cst is charged to is proportional to the voltage applied from the data line 171. In addition, a voltage increasing signal is input to a capacitor line (not shown) for each frame cycle while the second thin film transistor T2 is turned off and the gate potential of the first thin film transistor T1 is increased in response to the voltage applied through the capacitor line (not shown). Here, the gate potential of the first thin film transistor T1 is dependent on the voltage applied through the capacitor line and the potential charged in the capacitor Cst. The first thin film transistor T1 is turned on when the gate potential exceeds a threshold voltage. When the first thin film transistor T1 is turned on, a voltage applied to the common power line 172 is applied to the OLED LD through the first thin film transistor T1 so that the OLED LD emits light.

The second thin film transistor T2 of the OLED display may be the thin film transistor according to any of the embodiments illustrated in FIG. 1 to FIG. 10.

While this described technology has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor comprising:
a substrate;
a semiconductor layer formed over the substrate;
a gate insulating layer;
a first gate electrode substantially overlapping the semiconductor layer, wherein the gate insulating layer is interposed between the first gate electrode and the semiconductor layer;
an interlayer insulating layer;
a second gate electrode substantially overlapping the first gate electrode, wherein the interlayer insulating layer is interposed between the first and second gate electrodes; and source and drain electrodes electrically connected to the semiconductor layer,
wherein the first gate electrode is electrically connected to the second gate electrode.

2. The thin film transistor of claim 1, wherein the first gate electrode is positioned between the substrate and the semiconductor layer.

3. The thin film transistor of claim 1, further comprising a protective layer positioned between the semiconductor and the source and drain electrodes, wherein the source and drain electrodes are respectively connected to a source region and a drain region of the semiconductor layer through a first contact hole formed in the protective layer.

4. The thin film transistor of claim 3, further comprising a connection bridge formed over the protective layer, wherein the connection bridge is configured to electrically connect the first gate electrode to the second gate electrode through a second contact hole.

5. The thin film transistor of claim 1, wherein the semiconductor layer is positioned between the first gate electrode and the substrate.

6. The thin film transistor of claim 1, wherein the second gate electrode is electrically connected to the first gate electrode through a contact hole formed in the interlayer insulating layer.

7. The thin film transistor of claim 1, wherein the second gate electrode is positioned within a boundary of the first gate electrode.

8. The thin film transistor of claim 1, wherein portions of the source and drain electrodes substantially overlap the first gate electrode and wherein a region of the semiconductor layer is interposed between the source and drain electrodes and the first gate electrode.

9. The thin film transistor of claim 1, wherein the semiconductor layer is formed of an oxide semiconductor.

10. A thin film transistor array panel, comprising:
a substrate;
a gate line formed over the substrate;
a thin film transistor electrically connected to the gate line;
a data line electrically connected to the thin film transistor; and
a pixel electrode electrically connected to the thin film transistor,
wherein the thin film transistor comprises:
a semiconductor layer,
a gate insulating layer,
a first gate electrode substantially overlapping the semiconductor layer, wherein the gate insulating layer is interposed between the first gate electrode and the semiconductor layer,
an interlayer insulating layer, and
a second gate electrode substantially overlapping the first gate electrode, wherein the interlayer insulating layer is interposed between the first and second gate electrodes,
wherein the first gate electrode is electrically connect to the second gate electrode.

11. The thin film transistor array panel of claim 10, wherein the first gate electrode is positioned within a boundary of the second gate electrode.

12. The thin film transistor array panel of claim 10, wherein the thin film transistor further comprises source and drain electrodes electrically connected to the semiconductor layer, wherein the source and drain electrodes substantially overlap the first gate electrode, and wherein a region of the semiconductor layer is interposed between the overlap between the source and drain electrodes and the first gate electrode.

13. The thin film transistor array panel of claim 10, wherein the semiconductor layer is formed of an oxide semiconductor.

14. The thin film transistor array panel of claim 10, wherein the thickness of the interlayer insulating layer is substantially equal to or greater than the thickness of the gate insulating layer.

15. The thin film transistor array panel of claim 10, wherein the second gate electrode is electrically connected to the first gate electrode through a contact hole.

16. The thin film transistor array panel of claim 10, wherein the thin film transistor further comprises source and drain electrodes electrically connected to the semiconductor layer, wherein the source electrode comprises first and second source electrodes electrically connected to each other, wherein the drain electrode comprises first and second drain electrodes electrically connected to each other, and wherein the first source and first drain electrodes are formed over the substrate and separated from each other.

17. A thin film transistor, comprising:
a substrate; a semiconductor layer formed over the substrate;
a first gate electrode formed over the substrate and substantially overlapping the semiconductor layer;
a second gate electrode formed over the substrate and substantially overlapping the semiconductor layer;
a gate insulating layer interposed between the second gate electrode and the substrate; and
an interlayer insulating layer interposed between the first and second gate electrodes,
wherein the first gate electrode is electrically connected to the second gate electrode.

18. The thin film transistor of claim 17, wherein the thickness of the first gate electrode is greater than the thickness of the second gate electrode.

19. The thin film transistor of claim 17, wherein the thickness of the gate insulating layer is substantially equal to or greater than the thickness of the gate insulating layer.

20. The thin film transistor of claim 17, wherein the first gate electrode is positioned between the substrate and the second gate electrode and wherein the second gate electrode is positioned between the substrate and the semiconductor layer.
